(19) United States
(12) Patent Application Publication
(10) Pub. No.: US 2026/0040876 A1
(43) Pub. Date: Feb. 5, 2026

(54) STATION AND METHOD FOR MEASURING THE PRACTICLE CONTAMINATION OF A TRANSPORT ENCLOSURE FOR THE ATMOSPHERIC TRANSPORT AND STORAGE OF SEMICONDUCTOR WAFERS

(71) Applicant: PFEIFFER VACUUM, Annecy (FR)

(72) Inventors: Bertrand BELLET, Annecy Cedex (FR); Julien BOUNOUAR, Annecy Cedex (FR)

(73) Assignee: PFEIFFER VACUUM, Annecy (FR)

(21) Appl. No.: 19/100,850

(22) PCT Filed: Jul. 21, 2023
(86) PCT No.: PCT/EP2023/070271

§ 371 Date: Feb. 3, 2025

(30) Foreign Application Priority Data
Sep. 13, 2022 (FR) FR2209177

(51) Int. Cl. H01L 21/673; G01N 1/22; H01L 21/67; H01L 21/677

(52) U.S. Cl. CPC H01L 21/67393; G01N 1/2226; H01L 21/67253; H01L 21/67772

(57) ABSTRACT

A measurement station for measuring particle contamination in a transport enclosure for the atmospheric transport and storage of semiconductor wafers includes a particle counter and an interface designed to be coupled to the shell of a transport enclosure in place of the door. The interface includes a sampling orifice fluidly connected to the particle counter. The measurement station also includes a clean-gas injection device having at least one injection line including at least one injection nozzle to be fluidly connected to a ventilation port of the transport enclosure coupled to the interface for injecting clean gas into the transport enclosure, from outside the transport enclosure, through the at least one ventilation port of the transport enclosure.

The present invention relates to a measurement station for measuring the particle contamination of a transport enclosure for the atmospheric transport and storage of semiconductor wafers. The invention also relates to a corresponding measurement method.

In the semiconductor manufacturing industry, transport enclosures, notably standardized front-opening unified pod (FOUP) wafer transport and storage enclosures, are used to transport silicon wafers from one piece of equipment to another, or to store wafers between two manufacturing stages.

These transport enclosures are made of materials such as polycarbonate, which can in some cases accumulate contaminants, in particular organic, amine or acid contaminants. The silicon wafers spend a lot of time inside these closed enclosures. It is therefore essential to control the contamination in these containers, and in particular particle contamination.

To determine when an enclosure requires cleaning, a measurement device comprising a particle detector and an interface designed to be coupled to the shell of a transport enclosure in place of the door is known from document WO 2014083151. An interface measuring head with a sampling orifice connected to the particle detector and injection nozzles, injects a purging gas onto the walls of the shell from inside the enclosure in order to detach, sample and count the particles stuck to these walls.

This device makes it possible to determine the level of contamination on the internal surfaces of transport enclosures, in which particles are likely to fall off the walls onto the substrates contained in the transport enclosure when the enclosure is handled.

However, it has become important to monitor another element of the transport enclosure.

Originally, the ventilation ports of transport enclosures fitted with particle filters were only required to balance the pressure between the inside and the outside of the enclosures, notably to prevent air movements such as the ingress of air from the clean room into the enclosure when the door is opened, but also to avoid pressure drops in the enclosure that could create mechanical stresses that could be a source of contamination.

However, these ventilation ports are nowadays used as inlet orifices for nitrogen or ultra-dry air injected into the enclosure to purge the interior and limit the presence of gaseous contaminants (Airborne molecular contamination or AMC), thus guaranteeing an acceptable production yield. Some of these ventilation ports have even become more complex with the addition of numerous elements in addition to the filter, such as a check valve, diffusers, and the like, which can generate particles and clog the filters, or which can themselves be sources of leaks.

One consequence of this is that a faulty or unsuitable ventilation port filter immediately generates a high risk of contamination of the silicon wafers contained in the enclosure by the purging gas injected into the enclosure. The widespread practice of purging transport enclosures through ventilation ports means that particle filters are becoming the main source of contamination risk in transport enclosures.

However, existing solutions for monitoring particulate contamination in transport enclosures are not suitable for determining the level of contamination in ventilation port filters.

Indeed, using ultra-clean water to loosen the particles and counting said particles with a liquid particle counter to determine concentration does not enable tests to be carried out at a fast rate, and in particular does not enable the particle concentration of the filters to be monitored.

Injecting clean air into the transport enclosure to loosen and count the particles, as described in WO 2014083151 also does not specifically enable the filters in the enclosures to be monitored.

Another measurement method involves using a test silicon wafer previously subjected to particle measurement using particle measurement equipment used specifically for wafers. The measured test wafer is placed in the transport enclosure, which is coupled to a purge station to inject a purging gas through the ports of the enclosure. The test silicon wafer is then removed from the enclosure to count the particles deposited on the wafer by the measuring equipment, and the result is compared with the initial measurement. This measurement method is relatively slow and costly, and is not efficient enough for automated production control. Furthermore, wafer particle measurement equipment is not always available, since process equipment qualification tests for production take priority.

One of the objectives of the present invention is therefore to propose a station and a corresponding measuring method that enable a level of particle contamination of the particle filters of the ventilation ports of atmospheric transport enclosures to be measured in real time, directly in the manufacturing plant.

For this purpose, the invention relates to a measurement station for measuring particle contamination in a transport enclosure, notably an FOUP enclosure, for the atmospheric transport and storage of semiconductor wafers, said transport enclosure comprising a shell and a removable door capable of closing the shell, the shell having at least one ventilation port provided with a particle filter, for example from one to four ventilation ports, the measurement station comprising a particle counter and an interface designed to be coupled to the shell in place of the door, said interface comprising a sampling orifice fluidly connected to the particle counter.

The measurement station further comprises a clean-gas injection device comprising at least one injection line comprising at least one injection nozzle designed to be fluidly connected to a ventilation port of the transport enclosure coupled to the interface for injecting clean gas into the transport enclosure, from outside the transport enclosure, through the at least one ventilation port of the transport enclosure.

Injecting a clean gas into a ventilation port simulates the production risk conditions related to the purging of a transport enclosure via the ventilation port or ports. If a particle filter in the ventilation port poses a particulate contamination problem, this problem can be detected by taking a measurement with the particle counter, using particles sampled from inside the transport enclosure via the sampling orifice. The test conditions are the same as the conditions used for production. Real-time particle counting also enables production rates to be maintained.

The station can also have one or more of the features described below, taken individually or in combination.

The sampling orifice is for example arranged in a measuring head projecting from a base of the interface.

The measurement station can include a vacuum pump arranged downstream of the particle counter in the gas pumping direction.

The particle counter is for example an aerosol particle counter. The particle counter is for example optical. The pumping flow rate of the vacuum pump is for example 30 l/min (1.8 m³/h or 0.0005 m³/s).

To couple the transport enclosure to the measurement station and remove the door therefrom, the measurement station can comprise a chamber receiving the interface and having a lateral access and a load port arranged below the access. The load port can be coupled to the shell and to the door of the transport enclosure to move the door into the chamber and bring the inside of the shell into communication with the inside of the chamber.

The clean-gas injection device for example comprises as many injection nozzles as there are ventilation ports on the transport enclosure. According to another example, the clean-gas injection device comprises at least one plug designed to close a ventilation port, for example so that all ventilation ports are engaged with an injection nozzle or a plug. Alternatively, some ventilation ports can be left free.

The at least one injection nozzle for example comprises a sealing device providing a tight connection with the ventilation port.

The clean-gas injection device may comprise an actuator designed to push the injection nozzle or nozzles or the plug or plugs against a respective ventilation port, as applicable.

The clean-gas injection device can comprise at least one pressure sensor designed to measure the pressure in an injection line.

The clean-gas injection device can also include at least one flow control device, enabling the controlled injection of different gas flows, for example in the range 30 l/min (0.0005 m³/s) to 100 l/min (0.00167 m³/s), for example 50 l/min (0.00083 m³/s) on average and up to 100 l/min (0.00167 m³/s), in an injection line.

There is for example one pressure sensor and one flow control device per injection line.

The invention also relates to a method for measuring the particle contamination of a transport enclosure for the atmospheric transport and storage of semiconductor wafers, implemented in a measurement station as described above, in which a clean gas is injected into the transport enclosure, from outside the transport enclosure, through the at least one ventilation port of the transport enclosure, and the particles of a gas sample taken through the sampling orifice of the interface during injection are counted.

The measurement method can also have one or more of the features described below, taken individually or in combination.

According to an example embodiment, the clean-gas flow rate injected by the at least one injection nozzle is greater than the sampled-gas flow rate. For example, the clean gas flow rate injected into the at least one injection nozzle is greater than 6 l/min (0.0001 m³/s), for example greater than 30 l/min (1.8 m³/h or 0.0005 m³/s), for example greater than 50 l/min (3 m³/h or 0.000833333 m³/s), for example 80 l/min (4.8 m³/h or 0.00133333 m³/s). Injecting clean gas at a flow rate greater than the sampled-gas flow rate, and greater than the flow rate normally used to purge the transport enclosures under production conditions, subjects the transport enclosures to slightly more stress than during purging operations. This facilitates the removal of particles from the particle filter for counting.

The clean gas is for example nitrogen or compressed air of ISO 8573-1 quality class 1/1/1:

| | Solid particles | | | | | Oil |
|---|---|---|---|---|---|---|
| | Maximum number of particles per m³ | | | Dew | | content |
| Class | 0.1 to 0.5 μm | 0.5 to 1 μm | 1 to 5 μm | point | | in mg/m³ |
| 1 | 100 | 1 | 0 | −70° | C. | 0.01 |
| 2 | 100000 | 1000 | 10 | −40° | C. | 0.1 |
| 3 | — | 10000 | 500 | −20° | C. | 1 |
| 4 | — | — | 1000 | +3° | C. | 5 |
| 5 | — | — | 20000 | +7° | C. | — |
| 6 | — | — | — | +10° | C. | — |

According to an example embodiment, to measure the particle contamination of a transport enclosure having several ventilation ports, all of the ventilation ports of the transport enclosure are injected simultaneously and the number of particles is counted during this injection. This method makes it possible to determine an overall level of cleanliness for the particle filters in the transport enclosure.

According to another example embodiment, to measure the particle contamination of a transport enclosure having several ventilation ports, the ventilation ports are injected sequentially, either port by port in turn, or in sets of two or more ports at the same time, and the number of particles is counted during each injection. Sequencing helps to locate the problematic filter.

According to an example embodiment, a fault is identified in a ventilation port, in particular one with an abnormally high particle count, in particular to determine whether this is due to a fault in the particle filter, by measuring the pressure in the injection line via the pressure sensor during an injection, and comparing said pressure with a reference value, for example obtained in the injection line without faults.

The difference between the measured pressure and the reference value may indicate a fault in the ventilation port. If the measured pressure is lower than the reference value, this may indicate damage to the particle filter in the ventilation port, or a leaking element in the clean-gas injection device. If the measured pressure is higher than the reference value, this may indicate a malfunctioning valve in the ventilation port.

Other advantages and features are included in the description of a non-limiting example embodiment of the invention, and in the attached drawings in which:

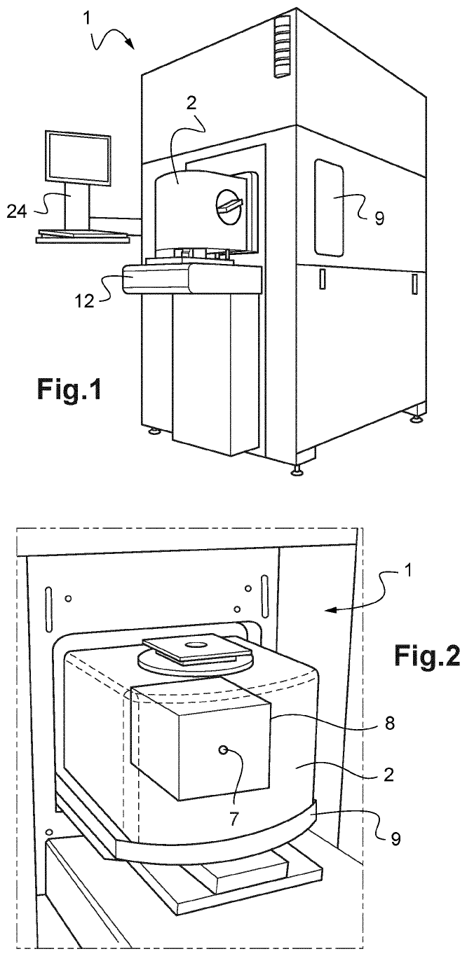

FIG. 1 is a perspective view of a particle contamination measurement station coupled to a transport enclosure.

FIG. 2 shows a magnified view of the shell of the transport enclosure coupled to the measurement station.

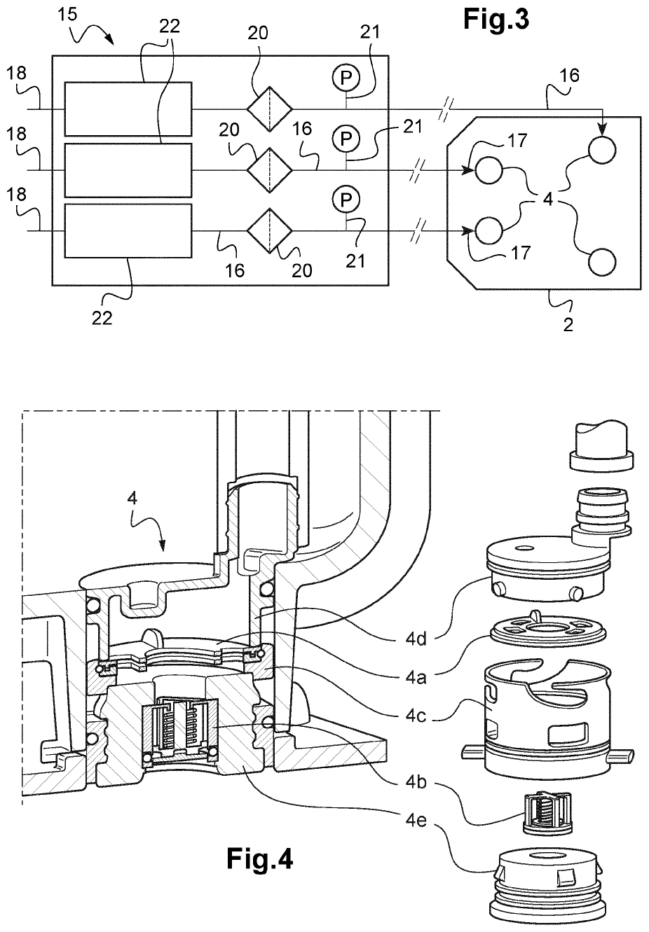

FIG. 3 is a schematic view of elements of the clean-gas injection device of the measurement station and a transport enclosure (bottom view).

FIG. 4 shows an example of a transport enclosure ventilation port in the assembled and in an exploded state.

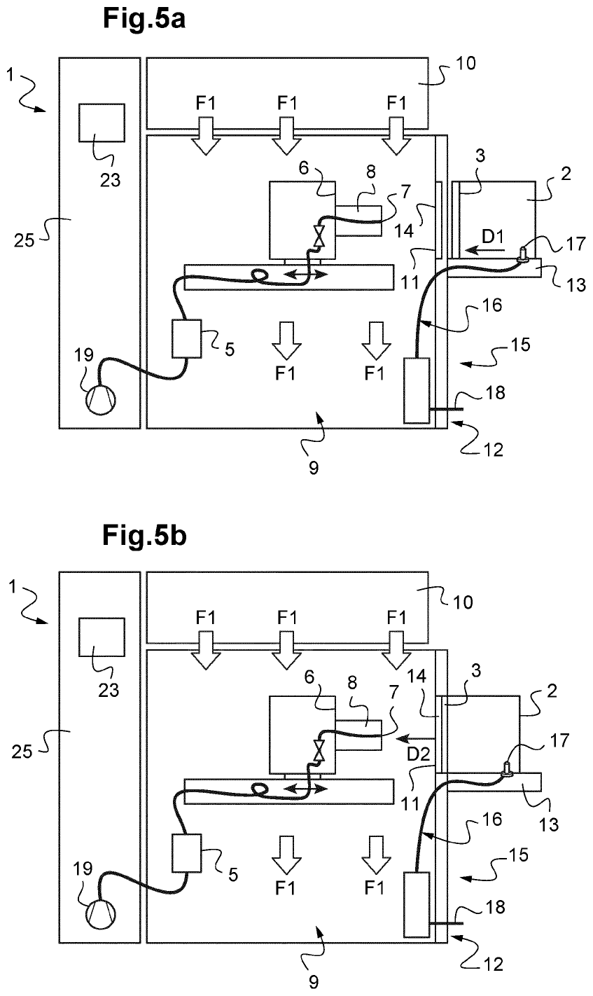

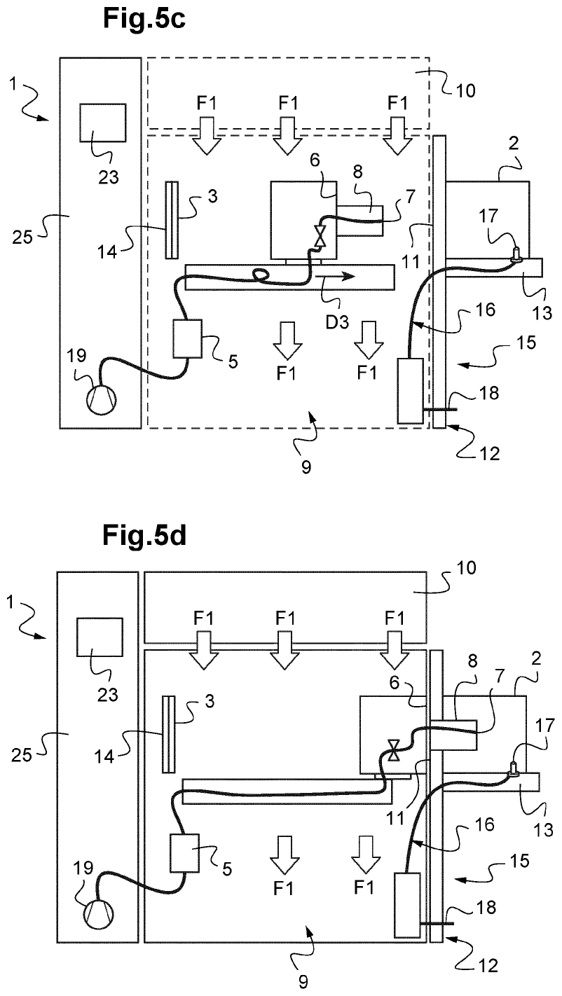

FIG. 5a is a schematic view of the measurement station and a transport enclosure.

FIG. 5b is a view similar and successive to FIG. 5a, with the load port of the measurement station coupled with the door of the transport enclosure.

FIG. 5c is a view similar and successive to FIG. 5b, with the load-port door and the door of the enclosure moved away from the access to a chamber of the measurement station.

FIG. 5d is a view similar and successive to FIG. 5c, with the interface coupled to the shell of the transport enclosure.

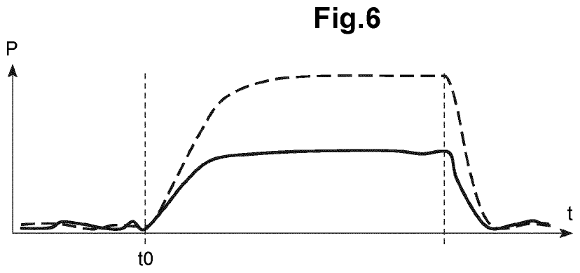

FIG. 6 is a graph of the pressure measured as a function of time during an injection, in an injection line of the clean-gas injection device with a fault (solid lines) and in the injection line without faults (dashed lines).

In these figures, identical elements are indicated using the same reference numbers.

The following embodiments are examples. Although the description refers to one or more embodiments, this does not necessarily mean that each reference sign refers to the same embodiment, or that the features apply only to one embodiment. Individual features of different embodiments may also be combined or swapped to provide other embodiments.

FIG. 1 shows a measurement station 1 for measuring particle contamination in a front-opening unified pod (FOUP) wafer transport and storage enclosure.

These transport enclosures have a confined interior air or nitrogen atmosphere under atmospheric pressure, i.e. a pressure roughly equivalent to that of the operating environment of the clean room, but separate therefrom.

As shown in FIGS. 2 and 5a, the transport enclosures comprise a shell 2 and a removable door 3 that can close the shell 2, the door 3 being dimensioned to enable wafers to be inserted into and removed from the enclosure. The shell 2 and the door 3 are made of materials such as polycarbonate. The inner side walls, bottom wall and door 3 are provided with slots to hold the wafers. The enclosure is relatively tight, but the level of the seal is such that slight leakage can occur through a gasket arranged between the shell 2 and the door 3.

The shell 2 in FOUP transport enclosures comprises at least one ventilation port 4, for example one to four ventilation ports 4, each fitted with a particle filter 4a to prevent particles from entering the transport enclosure (FIGS. 3 and 4). The ventilation ports 4 are arranged in the bottom of the shell 2, and notably enable the pressure to be balanced between the inside and the outside of the transport enclosure to prevent movements of air when the door is opened.

The ventilation ports 4 can only be formed by an orifice provided with a particle filter 4a, the gas being able to flow in and out simultaneously and indifferently through each ventilation port 4 of the enclosure. Other ventilation ports 4 may feature an inlet or outlet check valve 4b, arranged in a respective orifice, upstream or downstream of the particle filter 4a. The outlet check valves open in the event of a gas surplus inside the transport enclosure relative to the external atmospheric pressure, while the inlet check valves open in the event of negative pressure inside the enclosure. The ventilation ports 4 can also comprise other elements, such as gaskets, a support element 4c, a diffuser 4d, or a grommet 4e.

As shown in FIG. 5a, the measurement station 1 comprises a particle counter 5 and an interface 6 designed to be coupled with the shell 2 of a transport enclosure coupled to the measurement station 1, in place of the door 3.

The interface 6 comprises a sampling orifice 7 fluidly connected to the particle counter 5 via a sampling line. The sampling orifice 7 is for example arranged in a measuring head 8 projecting from a base of the interface 6, but in this case the substrates are removed from the transport enclosures before a measurement is taken.

The measurement station 1 can also include a vacuum pump 19 arranged downstream of the particle counter 5 in the gas pumping direction.

The gas sample is taken from the measurement volume of the shell 2 coupled to the interface 6 by suction through the sampling orifice 7. The quantity of particles contained in the gas sample taken is determined by the particle counter 5. The particle counter 5 is for example an aerosol particle counter, i.e. providing quantitative information on the suspended particles in a gaseous environment. The particle counter is for example optical, for example based on laser technology. The pumping rate of the vacuum pump 19 is for example 30 l/min (1.8 m³/h or 0.0005 m³/s).

To couple the transport enclosure to the measurement station 1 and remove the door 3 therefrom, the measurement station 1 can comprise a chamber 9, in particular with a controlled environment, the interface 6 notably being seated in the chamber. The chamber 9 is for example a clean room at atmospheric pressure. For example, the chamber is ISO 3 certified, in accordance with the ISO 146644-1 “mini-environment” standard. For this purpose, the chamber 9 can include a laminar-flow filter unit 10.

According to an example embodiment, the chamber 9 has a side access 11 and a load port 12 beneath the access 11. The load port 12 can be coupled to the shell 2 and to the door 3 of the transport enclosure to move the door 3 into the chamber 9 and bring the inside of the shell 2 into communication with the inside of the chamber 9.

For this purpose, the load port 12 comprises a platform 13 for receiving and positioning a transport enclosure. The platform 13 may comprise a presence sensor designed to check that the model of transport enclosure is compatible with the measurement station 1 receiving the enclosure. Furthermore, to be coupled with the shell 2, the platform 13 of the load port 12 comprises securing means for clamping the shell 2, then moving the shell in translation against the access 11 of the chamber 9 (arrow D1 in FIG. 5a). According to another example (not shown), the load port 12 comprises displacement means designed to move the securing means from the load port 12 towards the enclosure.

The load port 12 also comprises a load-port door 14. The load-port door 14 has approximately the same dimensions as the door 3 of the transport enclosure. The load-port door 14 notably closes the access 11 to the chamber 9 when there is no transport enclosure present. Bolt actuation means for locking and unlocking the locking members of door 3 are also provided.

The locking members for the door 3, which are known, are for example latches carried by the door 3, are actuated by radial or lateral sliding, and engage in the shell 2 of the transport enclosure when the transport enclosure is closed.

Once the locking members have been released, the bolt actuating means reversibly secure the door 3 to the load-port door 14. The doors 3, 14 can then be moved as a single unit out of the front area of the access 11 into the chamber 9 via an actuating mechanism for the load-port door 14.

The interface 6 can then be coupled to the shell 2 in place of the door 3, bringing the sampling orifice 7 connected to the particle counter 5 into fluid communication with the internal volume of the shell 2. The shell 2 and the interface 6 then form a “transport enclosure”.

The measurement station 1 also comprises a clean-gas injection device 15 with at least one injection line 16.

The injection line 16 comprises at least one injection nozzle 17 designed to be fluidly connected to a ventilation port 4 of the transport enclosure coupled to the interface 6 for injecting clean gas into the transport enclosure, from outside the transport enclosure, through the ventilation port 4 of the transport enclosure.

The injection nozzle 17 for example projects from the platform 13 at a position on the platform 13, so as to position the injection nozzle 17 opposite a ventilation port 4 of the transport enclosure once the shell 2 has been secured to the interface 6. The injection nozzle 17 is for example designed to be engaged in an orifice of the ventilation port 4 of the transport enclosure.

The clean-gas injection device 15 for example comprises as many injection nozzles 17 as there are ventilation ports 4 on the transport enclosure.

According to another example, the clean-gas injection device 15 comprises at least one plug designed to close a ventilation port 4, for example so that all ventilation ports 4 are engaged with an injection nozzle 17 or a plug.

Alternatively, some ventilation ports 4 can be left free.

The injection nozzles 17 for example comprise respective sealing devices providing a tight connection with the ventilation port 4. The sealing device is for example made of an elastic material such as silicone. This device is for example a suction cup, a ring gasket, a lip seal, or bellows surrounding the orifice of the injection nozzle 17. In another example, the sealing device is made of a rigid material, such as PEEK, and the seal can be made by compressing the sealing device.

The clean-gas injection device 15 may comprise an actuator designed to push the injection nozzle or nozzles 17 or the plug or plugs against a respective ventilation port 4, as applicable.

The injection line or lines 16 connecting the injection nozzles 17 are connected to a gas feed or feeds 18, such as gas outlets available on site (also known as “facilities”).

The injection line or lines 16 can also be fitted with particle filters 20 to filter any pollutant particles from the injected clean gas (FIG. 3).

The clean gas is for example nitrogen, or pure dry or ultra-dry air.

The injection flow rate of the clean gas into each injection nozzle 17 is for example between 6 l/min (0.0001 m³/s) and 30 l/min (1.8 m³/h or 0.0005 m³/s).

The clean-gas injection device 15 can also comprise at least one pressure sensor 21 designed to measure the pressure in an injection line 16 (FIG. 3). A fault in the ventilation port 4, for example a fault in the particle filter 4a, can then be identified by measuring the pressure in the injection line 16 and comparing said pressure with a reference value.

The clean-gas injection device 15 can also include at least one flow control device 22, enabling the controlled injection of different gas flows, for example in the range 30 l/min (0.0005 m³/s) to 100 l/min (0.00167 m³/s), for example 50 l/min (0.00083 m³/s) on average and up to 100 l/min (0.00167 m³/s), in an injection line 16.

There is for example one pressure sensor 21 and one flow control device 22 per injection line 16. The pressure sensor 21 is arranged downstream of the flow control device 22 and of the particle filter 20 in the flow direction of the clean gas in the injection line 16. Said sensor is also advantageously located as close as possible to the ventilation port 4 to improve measurement sensitivity.

The control means of the transport enclosure model, the bolt actuating means, the actuating mechanisms of the load-port door 14 and the clean-gas injection device 15 can be controlled by a processing unit 23 of the measurement station 1, such as a computer or controller. The processing unit 23 can be connected to a user interface 24, for example notably comprising a screen and a keyboard, as shown in FIG. 1.

The measurement station 1 also for example comprises an electrical cabinet 25 for powering and housing some or all of the electrical components of the station. The electrical cabinet 25 is advantageously offset laterally from the chamber 9, so as to be away from the laminar flow of filtered air, thus preventing contamination of the chamber 9 by the various components housed in the electrical cabinet 25.

The method for measuring the particle contamination of a transport enclosure for the atmospheric transport and storage of semiconductor wafers implemented in the measurement station 1 comprises the steps described below.

When the measurement station 1 is in the idle position, the interface 6 is arranged in the chamber 9, in which the access 11 is closed by the load-port door 14 (FIG. 5a).

When an operator or robot places a transport enclosure on the platform 13 of the load port 12, the load port 12 then positions and checks the transport enclosure model, then clamps the shell 2 of the enclosure and moves said shell against the access 11 of the chamber 9 (arrow D1 in FIG. 5a).

The bolt actuating means of the load-port door 14 then releases the locking members of the door 3 and rigidly connects the door 3 to the load-port door 14 (FIG. 5b).

The doors 3, 14 are then moved into the chamber 9 away from the access 11 (arrow D2 in FIG. 5b), bringing the internal volume of the shell 2 into communication with the internal volume of the chamber 9.

The interface 6 is then moved towards the shell 2 and is coupled to the shell 2 in place of the door 3. In the coupled state, the measuring head 8 is immobilized in the measurement volume defined by the interface 6 and the coupled shell 2.

A clean gas is then injected into the transport enclosure, from outside the transport enclosure, through the ventilation port or ports 4 of the transport enclosure, and the particles of a gas sample taken through the sampling orifice 7 of the interface 6 during injection are counted (in real time/simultaneously). The gas sample is taken from the measurement volume by suction through the sampling line. The quantity of particles contained in the gas sample taken is determined continuously by the particle counter 5.

Injecting a clean gas into a ventilation port 4 simulates the production risk conditions related to the purging of a transport enclosure via the ventilation port 4. If a particle filter 4a in the ventilation port 4 poses a particulate contamination problem, this problem can be detected by taking a measurement with the particle counter 5, using particles sampled from inside the transport enclosure. The test conditions are the same as the conditions used for production. Real-time particle counting also enables production rates to be maintained.

According to an example embodiment, the clean-gas flow rate injected by the at least one injection nozzle 17 is greater than the sampled-gas flow rate. For example, the clean gas flow rate injected into the at least one injection nozzle 17 is greater than 6 l/min (0.0001 m³/s), for example greater than 30 l/min (1.8 m³/h or 0.0005 m³/s), for example greater than 50 l/min (3 m³/h or 0.000833333 m³/s), for example 80 l/min (4.8 m³/h or 0.00133333 m³/s). Injecting clean gas at a flow rate greater than the sampled-gas flow rate, and greater than the flow rate normally used to purge the transport enclosures under production conditions, subjects the transport enclosures to slightly more stress than during purging operations. This facilitates the removal of particles from the particle filter 4a for counting.

The injection time is for example one minute per injection nozzle 17.

According to an example embodiment, all of the ventilation ports 4 of the transport enclosure are injected simultaneously and the number of particles is counted during this injection. This method makes it possible to determine an overall level of cleanliness for the particle filters 4a in the transport enclosure.

According to another example embodiment, the ventilation ports 4 are injected sequentially, either port by port in turn, or in sets of two or more ports at the same time, and the number of particles is counted during each injection. Sequencing enables the problematic ventilation port 4 to be located.

According to an example embodiment, a fault is identified in a ventilation port 4, in particular one with an abnormally high particle count, in particular to determine whether this is due to a fault in the particle filter 4a, by measuring the pressure in the injection line 16 via the pressure sensor 21 during an injection, and comparing said pressure with a reference value, for example obtained in the injection line 16 without faults determined during tuning or by calculation.

The difference between the measured pressure and the reference value may indicate a fault in the ventilation port 4. If the measured pressure is lower than the reference value, for example less than 20% of the reference value, this may indicate damage to the particle filter 4a in the ventilation port 4, or a leaking element in the clean-gas injection device 15. If the measured pressure is higher than the reference value, this may indicate a malfunctioning valve 4b in the ventilation port 4.

Indeed, when the clean gas is injected through the injection nozzle 17 into the ventilation port 4, the particle filter 4a “brakes” the clean gas, resulting in a stabilized pressure increase during steady-state injection. If the particle filter 4a is damaged, incorrectly positioned or missing, this pressure stabilizes at a lower value.

This is shown by the graph in FIG. 6, which shows the pressure as a function of time measured during an injection starting at to in an injection line 16 with a fault (solid lines) and in the injection line 16 without faults (dashed lines).

This graph shows that the pressure measured in the injection line 16 is well below the reference value for the fault-free injection line 16, at least 20% lower, and in this case almost 50% lower, which may indicate a fault in the particle filter 4a of the ventilation port 4.

When the measurements are complete, the interface 6 is removed from the shell 2 and the transport enclosure is closed and released to be sent for cleaning, or to continue the transporting or storage operation, depending on the cleanliness thereof.

1-9. (canceled)

10. A measurement station for measuring particle contamination in a transport enclosure for the atmospheric transport and storage of semiconductor wafers, said transport enclosure comprising a shell and a removable door configured to close the shell, the shell having at least one ventilation port provided with a particle filter, the measurement station comprising:
a particle counter and an interface configured to be coupled to the shell in place of the door, said interface comprising a sampling orifice fluidly connected to the particle counter; and
a clean-gas injection device comprising at least one injection line comprising at least one injection nozzle configured to be fluidly connected to a ventilation port of the transport enclosure coupled to the interface for injecting clean gas into the transport enclosure, from outside the transport enclosure, through the at least one ventilation port of the transport enclosure.

11. The measurement station according to claim 10, wherein the clean-gas injection device comprises at least one pressure sensor configured to measure the pressure in the at least one injection line.

12. A method for measuring the particle contamination of the transport enclosure for the atmospheric transport and storage of semiconductor wafers, implemented in the measurement station according to claim 10, comprising:
injecting the clean gas into the transport enclosure, from outside the transport enclosure, through the at least one ventilation port of the transport enclosure; and
counting the particles of a gas sample taken through the sampling orifice of the interface during injection.

13. The measurement method according to claim 12, wherein a clean-gas flow rate injected by the at least one injection nozzle is greater than a sampled-gas flow rate.

14. The measurement method according to claim 13, wherein the clean-gas flow rate injected into the at least one injection nozzle is greater than 0.0001 m³/s.

15. The measurement method according to claim 13, wherein the clean-gas flow rate injected into the at least one injection nozzle is greater than 0.0005 m³/s.

16. The measurement method according to claim 12, wherein the clean gas is nitrogen or pure dry air.

17. The measurement method according to claim 12, wherein the transport enclosure comprises a plurality of the ventilation ports, and all of the ventilation ports of the transport enclosure are injected simultaneously and the number of particles is counted during the injection.

18. The measurement method according to claim 12, wherein the transport enclosure comprises a plurality of the ventilation ports, and all of the ventilation ports of the transport enclosure are injected sequentially and the number of particles is counted during each injection.

19. The measurement method according to claim 12, wherein a fault in the ventilation port is identified by measuring the pressure in the injection line and comparing said pressure with a reference value.
